(19) United States
(12) Patent Application Publication
(10) Pub. No.: US 2026/0229419 A1
(43) Pub. Date: Aug. 6, 2026

(54) FT SWITCH FRONT SAFETY BARRIER

(71) Applicant: ABB Schweiz AG, Baden (CH)

(72) Inventors: Alex Kobylanski, Monroe, NC (US); Joemoan Xavier, Camas, WA (US); Glenn Goldfarb, DeBary, FL (US)

(21) Appl. No.: 19/045,780

(22) Filed: Feb. 5, 2025

(51) Int. Cl. H01H 9/02; G01R 1/20

(52) U.S. Cl. CPC H01H 9/02; G01R 1/206

(57) ABSTRACT

A safety barrier for a switch for multi-circuit testing is described. The safety barrier includes a base, at least one first flap extending from the base, at least one second flap extending from the base, and at least one flap pair comprising a corresponding first flap of the at least one first flap and a corresponding second flap of the at least one second flap. Each flap pair of the at least one flap pair is adapted to partially house a test switch blade from the switch for multi-circuit testing.

### TECHNICAL FIELD

The field of disclosure relates generally to safety barriers, and more particularly, to safety barriers for switches for multi-circuit testing.

### BACKGROUND

Currently in the industry, switches for use in multi-circuit testing of switchboard relays, meters, and instruments expose switch operators to safety risks due to ease of contact with live elements within the switches. However, existing protective measures are limited in their applications and effectiveness to reduce these safety risks. For example, dividers are a commonly used protective measure. However, dividers may offer limited protection to operators, may expose operators to additional safety risks to install these dividers, and may not be compatible with additional components for use with these switches.

Based on the foregoing, a need exists for an easy to install, more reliable, and safer safety barrier for these switches.

This background section is intended to introduce the reader to various aspects of art that may be related to various aspects of the present disclosure, which are described and/or claimed below. This discussion is believed to be helpful in providing the reader with supporting information to facilitate a better understanding of the various aspects of the present disclosure. Accordingly, it should be understood that these statements are to be read in this light, and not as admissions of prior art.

### BRIEF DESCRIPTION

In one aspect, a safety barrier for a switch for multi-circuit testing is described. The safety barrier includes a base, at least one first flap extending from the base, at least one second flap extending from the base, and at least one flap pair comprising a corresponding first flap of the at least one first flap and a corresponding second flap of the at least one second flap. Each flap pair of the at least one flap pair is adapted to partially house a test switch blade from the switch for multi-circuit testing.

In another aspect, a switch for multi-circuit testing is described. The switch includes a switch body comprising at least one test switch blade and cover studs extending from the switch body. Further, the switch for multi-circuit testing includes a safety barrier coupled to the switch body, the safety barrier includes peripheral portions configured to receive the cover studs, a base connecting the peripheral portions, at least one first flap extending from the base, at least one second flap extending from the base, and at least one flap pair comprising a corresponding first flap of the at least one first flap and a corresponding second flap of the at least one second flap. Each flap pair of the at least one flap pair is adapted to partially house one test switch blade from the at least one test switch blade.

In yet another aspect, a method of using a switch safety barrier is described. The method includes providing a switch safety barrier on a switch for multi-circuit testing. The safety switch barrier includes peripheral portions configured to receive cover studs of the switch, a base connecting the peripheral portions, at least one first flap extending from the base, at least one second flap extending from the base, and at least one flap pair comprising a corresponding first flap of the at least one first flap and a corresponding second flap of the at least one second flap. Each flap pair of the at least one flap pair is adapted to partially house one test switch blade from the at least one test switch blade The method also includes receiving a handle associated with at least one test switch blade within the switch for multi-circuit testing by a flap pair associated with the at least one test switch blade to open the at least one test switch blade and, thereby, expanding a space between the flap pair while the handle passes through the flap pair. Further, the method includes contracting the space between the flap pair after the handle passes through the flap pair and the at least one test switch blade is in an open position.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1A depicts a front view of a safety barrier for a switch for multi-circuit testing as described herein;

FIG. 1B depicts a perspective view of the safety barrier for a switch for multi-circuit testing of FIG. 1A;

FIG. 1C depicts a side perspective view of the safety barrier for a switch for multi-circuit testing of FIG. 1A;

FIG. 2 depicts a front view of a switch for multi-circuit testing with test switch blades in a closed position, as described herein;

FIGS. 3A and 3B depict a detailed view of a flap pair of the switch for multi-circuit testing of FIG. 2 during opening of a test switch blade;

FIG. 4 depicts a perspective view of the switch for multi-circuit testing of FIG. 2 with test switch blades in an open position;

FIG. 5 depicts a detailed view of the switch for multi-circuit testing of FIG. 2 with a blocking clip installed and test switch blades in an open position; and

FIG. 6 is a flow chart outlining a method for using a switch safety barrier.

Corresponding reference characters indicate corresponding parts throughout the several views of the drawings. Although specific features of various examples may be shown in some drawings and not in others, this is for convenience only. Any feature of any drawing may be referenced or claimed in combination with any feature of any other drawing.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure. The following terms are used in the present disclosure as defined below.

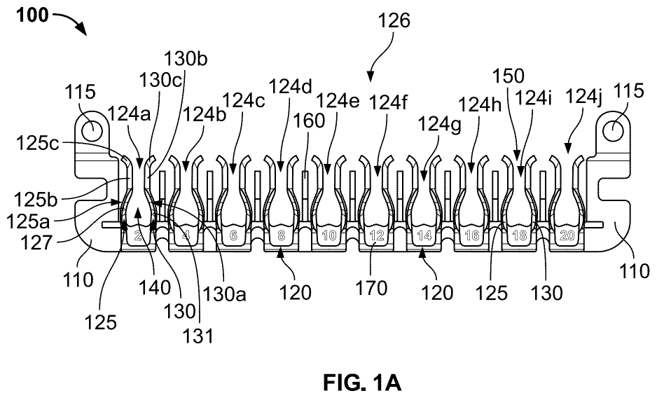

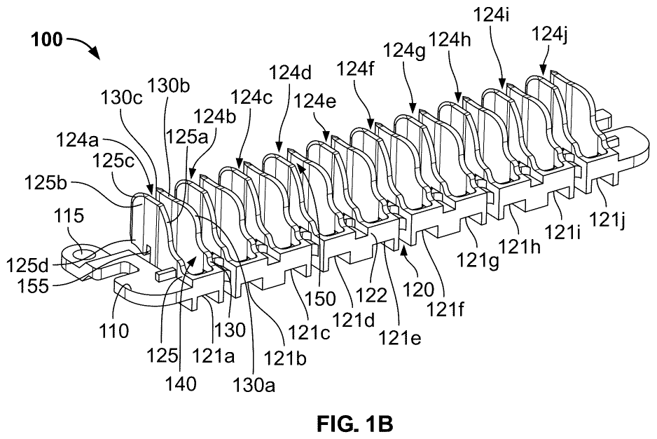

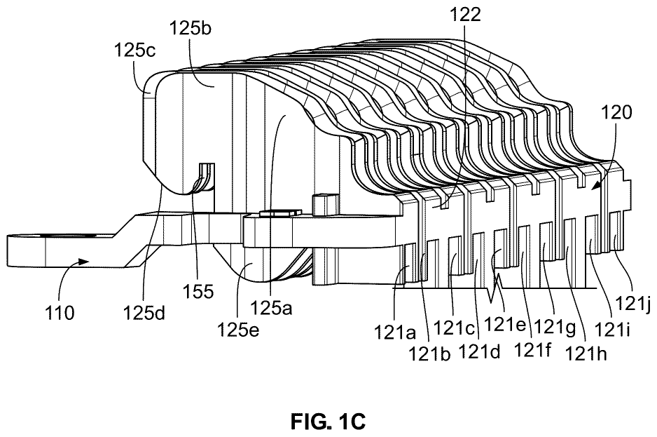

FIG. 1A depicts a front view of a safety barrier 100 for a switch for multi-circuit testing, as described herein. FIG. 1B depicts a perspective view of the safety barrier 100 for a switch for multi-circuit testing of FIG. 1A. FIG. 1C depicts a side perspective view of the safety barrier for a switch for multi-circuit testing of FIG. 1A. The safety barrier 100 comprises a plurality of peripheral portions 110 disposed on opposing sides of the safety barrier 100. For example, the safety barrier 100 may comprise a first peripheral portion 110 disposed on a first side (e.g., a left side) of the safety barrier and a second peripheral portion 110 disposed on a second side (e.g., a right side) of the safety barrier 100, where the first and second sides are on opposing sides of the safety barrier 100. Each of the plurality of peripheral portions 110 may include a coupling aperture 115. The coupling aperture 115 may be used to couple the safety barrier 100 to a switch for multi-circuit testing to allow the safety barrier 100 to be used with the switch for multi-circuit testing.

As shown in FIGS. 1A and 1B, the safety barrier 100 includes a base 120 that extends between and connects the peripheral portions 110. The base 120 may be sized and configured to extend along a length of a switch for multi-circuit testing to align the safety barrier 100 with the switch for multi-circuit testing. The base 120 may connect the plurality of peripheral portions 110 to form a wide U-shape.

In an embodiment, the base 120 may include at least one clip slot 121a, 121b, 121c, 121d, 121e, 121f, 121g, 121h, 121i, 121j extending through a portion of the base 120. Each of the at least one clip slot 121a, 121b, 121c, 121d, 121e, 121f, 121g, 121h, 121i, 121j may correspond to one of at least one flap pair 124a, 124b, 124c, 124d, 124e, 124f, 124g, 124h, 124i, 124j formed on the base 120, described in more detail below. Each clip slot 121a, 121b, 121c, 121d, 121e, 121f, 121g, 121h, 121i, 121j may be adapted to align an alligator clip (not shown) for attachment to a crimped section of a test switch blade that is positioned within the corresponding flap pair 124a, 124b, 124c, 124d, 124e, 124f, 124g, 124h, 124i, 124j. Additionally, the base 120 may include reinforced portions 122 along the length of the base 120 to provide support and rigidity to the base 120 and/or the safety barrier 100. The reinforced portions 122 may prevent the base 120 and/or safety barrier 100 from breaking during use by operators and increase durability of the safety barrier 100. The reinforced portions 122 may be disposed adjacent clip slots 121a, 121b, 121c, 121d, 121e, 121f, 121g, 121h, 121i, 121j. For example, the base 120 may include reinforced portions between clips slots (e.g., between clip slot 121b and clip slot 121c, between clip slot 121d and clip slot 121e, and the like) and/or above the clip slots 121a, 121b, 121c, 121d, 121e, 121f, 121g, 121h, 121i, 121j.

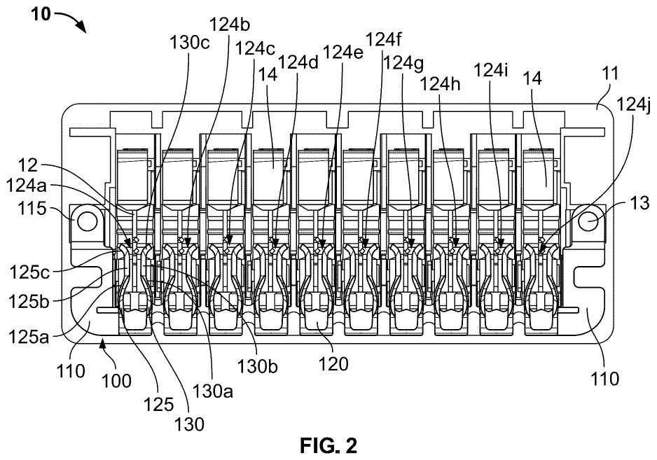

As discussed above, the base 120 comprises at least one flap pair 124a, 124b, 124c, 124d, 124e, 124f, 124g, 124h, 124i, 124j. Each flap pair comprises a corresponding first flap 125 paired with a corresponding second flap 130. For example, each flap pair may include a first flap 125 as a left flap in the flap pair 124 and a second flap 130 as a right flap in the flap pair 124. Each flap pair 124 may be sized to protect against insertion of objects, such as fingers, hands, large tools, and the like. This may prevent accidental touching of live components during use of switches for multi-circuit testing. As shown in FIGS. 1 and 2, the safety barrier 100 may include a plurality of flap pairs 124a, 124b, 124c, 124d, 124e, 124f, 124g, 124h, 124i, 124j. Each of flap pair is adapted to partially house a test switch blade from a switch for multi-circuit testing to allow switch operators to safely access the test switch blade. For example, the safety barrier 100 may include ten flap pairs 124a, 124b, 124c, 124d, 124e, 124f, 124g, 124h, 124i, 124j but is not limited thereto. The safety barrier 100 may include any number of flap pairs as required for use with a switch for multi-circuit testing, such as including a flap pair for each test switch blade from the switch for multi-circuit testing.

The safety barrier 100 comprises at least one first flap 125 extending from the base 120. The at least one first flap 125 may include any number of first flaps to correspond to a number flap pairs needed. Each of the at least one first flap 125 may extend from a portion of the base 120 that is adjacent to a space 126 between the peripheral portions 110. The at least one first flap 125 may extend into the space 126 between the peripheral portions 110. For example, each of the at least one first flap 125 may extend from a portion of the base 120 closest to space 126 into the space 126 within the wide U-shaped formed by the peripheral portions 110 and the base 120. Accordingly, each of the at least one first flap 125 may be disposed within the space 126 between the peripheral portions 110.

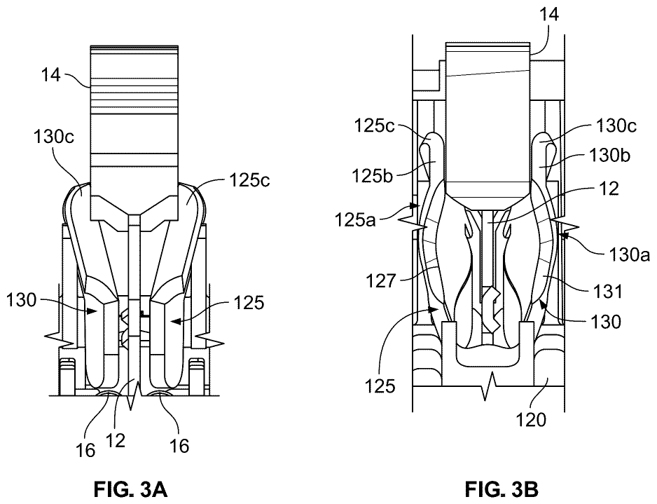

In an embodiment, each first flap 125 of the at least one first flap 125 may include a plurality of first flap portions to define the structure of each first flap 125. The plurality of first flap portions may include a first flap first portion 125a. A first end of the first flap first portion 125a is connected to the portion of the base 120 that adjacent to the space 126. The first flap first portion 125a is concave relative to the second flap 130. In an embodiment, the first flap first portion 125a may include a chamfered edge 127 along an edge of the first flap first portion 125a that is to be disposed distal from a switch for multi-circuit testing. The chamfered edge 127 may allow the first flap first portion 125a to guide a handle on a switch for multi-circuit testing, described in more detail in FIGS. 3A and 3B.

Further, the plurality of first flap portions may include a first flap second portion 125b extending from a second end of the first flap first portion 125a, opposite of the first end of the first flap first portion 125a. The first flap second portion 125b may extend between and connect the first flap first portion 125a and a first flap third portion 125c. Additionally, the plurality of first flap portions may include first flap third portion 125c. The first flap third portion 125c may extend from a portion of the first flap second portion 125b at an end of the first flap second portion 125b that is distal from the first flap first portion 125a. The first flap third portion 125c is convex relative to the second flap 130. Additionally, in an embodiment, the first flap third portion 125c may include a slanted portion 125d, shown in FIG. 1B, at a portion of the first flap third portion 125c to be positioned closer to a switch for multi-circuit testing. The slanted portion 125d may create sufficient clearance to allow for space for a current jack of a switch for multi-circuit testing when the safety barrier 100 is positioned on a switch for multi-circuit testing. Additionally, the slanted portion 125d may be adapted to engage a current jack to prevent excessive movement of safety barrier 100 during closing of a test switch blade, as described in more detail below.

In addition, the plurality of flap portions may include a first flap lower portion 125e, as shown in FIG. 1C. The first flap lower portion 125e defines an edge of the first flap 125 that is to be disposed proximal to a switch for multi-circuit testing. The first flap lower portion 125e may be adapted to engage a portion of a switch for multi-circuit testing during closing of a test switch blade. For example, the first flap lower portion 125e may be adapted to engage a hinge 16, shown in FIG. 3A, for a test switch blade, such as test switch blade 12, during closing of a test switch blade. In an embodiment, the first flaw lower portion 125e may be a rounded shape to allow the safety barrier 100 and/or the first flap 125 to roll in a downward direction while the first flap lower portion 125e is engaged with a portion of a switch for multi-circuit testing during closing of a test switch blade, as described below.

The safety barrier 100 also includes at least one second flap 130 extending from the base 120. The at least one second flap 130 may comprise any number of second flaps. Each flap pair 124a-124j includes a first and second flap 125 and 130 respectively. Each of the at least one second flap 130 may extend into a space 126 between the peripheral portions 110 from a portion of the base 120 adjacent to the space 126. For example, each of the at least one second flap 130 may extend into the space 126 within the wide U-shaped formed by the peripheral portions 110 and the base 120 from a portion of the base 120 closest to space 126. Accordingly, each of the at least one second flap 130 may be disposed within the space 126 between the peripheral portions 110.

In an embodiment, each second flap 130 of the at least one second flap 130 may include a plurality of second flap portions to define the structure of each second flap 130. The plurality of second flap portions may include a second flap first portion 130a. A first end of the second flap first portion 130a is connected to the portion of the base 120 adjacent to the space 126. The second flap first portion 130a is concave relative to the first flap 130 and/or first flap first portion 130a. The first flap first portion 125a and the second flap first portion 125b may define a bulbous-shaped spacing between the first flap first portion 125a and the second flap first portion 125b. The bulbous-shaped spacing between the second flap first portion 130a and the first flap first portion 125a may allow a user to maintain visibility of a make before break action for each test switch blade for a switch for multi-circuit testing. In an embodiment, the second flap first portion 130a may include a chamfered edge 131 along an edge of the second flap first portion 130a that is to be disposed distal from a switch for multi-circuit testing. The chamfered edge 131 may be similar to chamfered edge 127 and allow the first flap first portion 125a and second flap first portion 130a to guide a handle on a switch for multi-circuit testing together, as described in more detail in FIGS. 3A and 3B.

Further, the plurality of second flap portions may include a second flap second portion 130b. The second flap second portion 130b may extend from a second end of the second flap first portion 130a, opposite of the first end of the second flap first portion 130a. The second flap second portion 130b may extend between and connect the second flap first portion 130a and a second flap third portion 130c. The second flap second portion 130b may be disposed substantially parallel to the first flap second portion 125b. Additionally, the plurality of second flap portions may include the second flap third portion 130c. The second flap third portion 130c may extend from a portion of the second flap second portion 130b at an end of the second flap second portion that is distal from the first flap first portion 125a. The second flap third portion 130c is convex relative to the second flap 130. The second flap third portion 130c and first flap third portion 125c may define a widened channel to engage with a front portion of a handle from a switch for multi-circuit testing and allow the handle to pass through the flap pair, as described in more detail with respect to FIGS. 3A and 3B. The widened channel defined by the second flap third portion 130c and first flap third portion 125c may also be adapted to allow the flap pair to accommodate a handle that may be bent and/or positioned at an angle. Additionally, in an embodiment, the second flap third portion 130c may include slanted portion (not shown), similar to slanted portion 125d, at a portion of the second flap third portion 130c to be positioned closer to a switch for multi-circuit testing. The slanted portion may create sufficient clearance to allow for space for a current jack of a switch for multi-circuit testing when the safety barrier 100 is positioned on a switch for multi-circuit testing. Additionally, the slanted portion may be adapted to engage a current jack to prevent over movement of safety barrier 100 during closing of a test switch blade, as described in more detail below.

In addition, the plurality of second flap portions may include a second flap lower portion (not shown), similar to first flap lower portion 125e. The second flap lower portion defines an edge of the second flap 130 that is to be disposed proximal to a switch for multi-circuit testing. The second flap lower portion may be adapted to engage a portion of a switch for multi-circuit testing during closing of a test switch blade. For example, the second flap lower portion may be adapted to engage a hinge 16, shown in FIG. 3A, for a test switch blade, such as test switch blade 12, during closing of a test switch blade. In an embodiment, the second flaw lower portion may be a rounded shape to allow the safety barrier 100 and/or the second flap 130 to roll in a downward direction while the second flap lower portion 130 is engaged with a portion of a switch for multi-circuit testing during closing of a test switch blade, as described below.

In addition, the safety barrier 100 may include a test probe guiding channel 140. The test probe guiding channel 140 may be defined by an interior of the first flap first portion 125a, an interior of the second flap first portion 130a, and a portion of the base 120 disposed between the first flap 125 and the second flap 130. The concave shape of the first flap first portion 125a and the second flap first portion 130a may define a substantially bulbous cross-sectional shape for the test probe guiding channel 140. The substantially bulbous cross-sectional shape may be sized to allow for insertion of a test probe (not shown). Additionally, the substantially bulbous cross-sectional shape may allow the test probe guiding channel 140 to be used to direct the test probe into a desired alignment for proper use of the test probe and testing of a test switch blade. Additionally, bulbous cross-sectional shape may be sized of the test probe guiding channel 140 may protect against insertion of objects, such as fingers, hands, large tools, and the like to prevent accidental touching of live components during use of switches for multi-circuit testing.

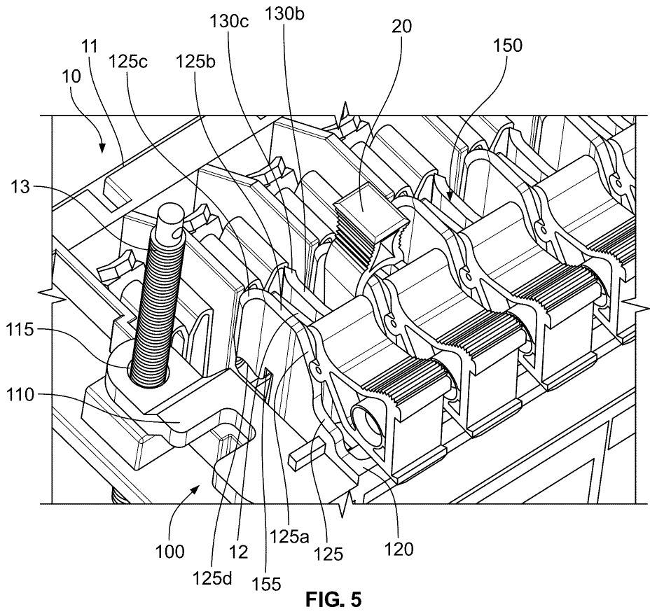

The safety barrier 100 may additionally include a clip receiving channel 150. The clip receiving channel 150 may be defined by an exterior of the first flap second portion 125b and an exterior of the second flap second portion 130b. The first flap second portion 125b and the second flap second portion 130b may define a narrow portion of the spacing between the first flap 125 and the second flap 130. The narrowed spacing between the first flap 125 and the second flap 130 may allow for the clip receiving channel to receive a clip 20 (shown in FIG. 5) without over expansion of the clip. Additionally, the first flap second portion 125b and second flap second portion 130b may each include a snap fit channel 155 configured to receive a corresponding protrusion (not shown) on the clip 20 while the clip 20 is being attached. The snap fit channel 155 may allow the clip 20 to snap fit into engagement with the first flap second portion 125b and the second flap second portion 130b. The snap fit channel 155 may be disposed on a portion of each first flap second portion 125b and second flap second portion 130b that corresponds to protrusions on the clip 20. The clip 20 (shown in FIG. 5) may be used to bias the first flap second portion 125b and second flap second portion 130b against each other and close the spacing between the flap pair 124 to prevent unintentional opening of a test switch blade.

The safety barrier 100 may additionally include at least one blocking rib 160 extending from the base between a first flap pair and a second flap pair of the at least one flap pair. For example, safety barrier 100 may include a blocking rib 160 between two flap pairs that are adjacent to each other. More specifically, the blocking rib 160 may extend from the base with a second flap 130 disposed adjacent to a left of the blocking rib 160 and a first flap 125 disposed adjacent to a right side of the blocking rib. The blocking rib 160 may be adapted to prevent accidental insertion of a test probe into incorrect locations within a switch for multi-circuit testing.

Further, the safety barrier 100 may include at least one visual switch indicator 170. Each visual switch indicator 170 may correspond with one flap pair of the at least one flap pair 124. The visual switch indicator 170 positioned on a portion of the base 120 between the first flap 125 and the second flap 130 of the corresponding flap pair 124. The visual switch indicator 170 may be a letter, number, symbol, and the like to indicate a terminal number assigned to corresponding pole positions for the test switch blade housed by the at least one flap pair. Additionally, the visual switch indicator 170 may be printed, hot stamped, adhered to, and the like the base.

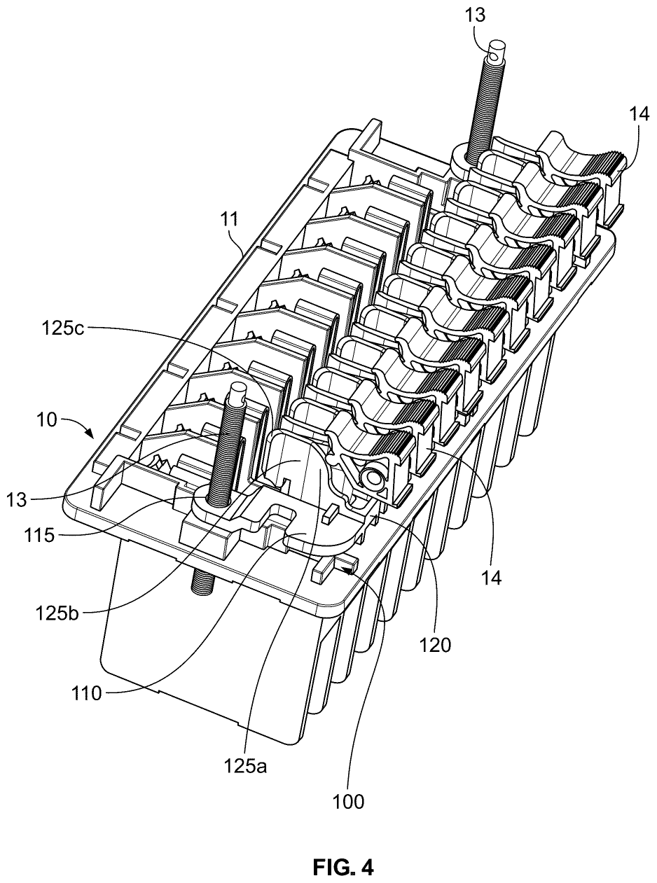

FIG. 2 depicts a top view of a switch for multi-circuit testing 10 with test switch blades 12 in a closed position, as described herein. The switch for multi-circuit testing 10 can be used for multi-circuit testing of switchboard relays, meters, and instruments. The switch for multi-circuit testing 10 comprises a switch body 11. The switch body 11 is adapted to house at least one test switch blade 12. Each test switch blade 12 may be used to control a flow of electricity within a circuit. Each test switch blade 12 may be actuated between a closed position, as shown in FIG. 2, and an open position, as shown in FIGS. 4 and 5. Each test switch blade 12 includes a handle 14 to allow an operator to actuate the test switch blade 12 between the open and closed position. The switch 10 comprises a plurality of cover studs 13 disposed on opposing sides of the switch body 11. For example, the switch may comprise a first cover stud disposed on a first side (e.g., a left side) of the switch body 11 and a second cover stud 13 disposed on a second side (e.g., a right side) of the switch body 11, where the first and second sides are on opposing sides of the switch body 11.

The switch for multi-circuit testing 10 includes a safety barrier 100 coupled to the switch body 11. As described above, the safety barrier 100 includes peripheral portions 110 each with a coupling aperture 115 that is adapted to receive the cover studs 13 for coupling of the safety barrier 100 to the switch for multi-circuit testing 10. As shown in FIG. 4, the cover studs 13 may extend through corresponding coupling apertures 115. For example, the safety barrier 100 may include a first peripheral portion 110 (e.g., left peripheral portion) with a coupling aperture 115 with a left cover stud 13 of the switch body 11 extending therethrough and a second peripheral portion 110 (e.g., right peripheral portion) with a coupling aperture 115 with a right cover stud 13 of the switch body 11 extending therethrough. The coupling apertures 115 may enable the safety barrier 100 to be coupled to existing switches quickly and easily without the need for extensive disassembly of these switches. Further, the coupling apertures 115 and cover studs 13 may be used to properly position and align the safety barrier 100 for use with the switch for multi-circuit testing 10. Once positioned on the cover studs 13, the safety barrier 100 may be secured in position on the switch body 11 by a washer and nut tightened onto each cover stud 13.

FIGS. 3A and 3B depict a detailed view of a flap pair of the switch for multi-circuit testing 10 of FIG. 3 during opening of a blade 12. During opening of a test switch blade 12 from the closed position, a widened channel defined by the second flap third portion 130c and first flap third portion 125c receives a bottom portion of a handle 14 to allow the handle 14 to engage with the second flap third portion 130c and first flap third portion 125c, as shown in FIG. 3A. Once the second flap third portion 130c and first flap third portion 125c are engaged with the handle 14, handle 14 may press against the second flap third portion 130c and first flap third portion 125c and cause the first flap 125 and the second flap 130 to flex outwardly. The outward flex of the first flap 125 and the second flap 130 causes the space between the first flap 125 and the second flap 130 to expand, as shown in FIG. 3B. The expanded space allows the handle 14 to pass between the first flap 125 and the second flap 130 and actuate the test switch blade 12 into the open position. In an embodiment, the safety barrier 100 may be made of a polycarbonate material and/or any other suitable plastic material to allow for the safety barrier to function as described herein.

FIG. 4 depicts a perspective view of the switch for multi-circuit testing of FIG. 2 with blades in an open position. FIG. 5 depicts a detailed view of the switch for multi-circuit testing of FIG. 2 with blades in an open position. As described above, the safety barrier 100 may additionally include a clip receiving channel 150 be defined by an exterior of the first flap second portion 125b and an exterior of the second flap second portion 130b. The clip receiving channel 150 may be configured to receive a clip 20 to bias the first flap second portion 125b and second flap second portion 130b towards each other, as shown in FIG. 5, and block a handle 14 from passing through a flap pair 124 and prevent accidental closing of an open test switch blade 12. Additionally, the first flap second portion 125b and second flap second portion 130b may each include a snap fit channel 155 disposed on a portion of each first flap second portion 125b and second flap second portion 130b to correspond to a protrusion on the clip 20. The snap fit channel 155 may be adapted to receive the protrusion on the clip 20 during attachment of the clip 20 to allow the clip 20 to snap fit into engagement with the first flap second portion 125b and the second flap second portion 130b. Additionally, the clip 20 may be used allow a user to quickly identify an open state for any of the at least one test switch blade 12.

During closing of a test switch blade 12 from the open position, the chamfered edge 131 of the second flap first portion 130a and the chamfered edge 127 of the first flap first portion 125a receives a bottom portion of a handle 14 to allow the handle 14 to engage with the second flap first portion 130a and first flap first portion 125a. Once the second flap first portion 130a and first flap first portion 125a are engaged with the handle 14, handle 14 may move along the second flap first portion 130a and first flap first portion 125a and press against the second flap first portion 130a and first flap first portion 125a and cause the safety barrier 100 and/or the first flap 125 and the second flap 130 to be pushed and roll downward. More specifically, as the handle 14 moves along the second flap first portion 130a and first flap first portion 125a, the handle 14 may press against the first flap 125 and the second flap 130 and the first flap lower portion 125e and second flap lower portion may each also press against a hinge 16 for a corresponding test switch blade 12 that is partially housed between the first flap 125 and the second flap 130. Further, while the first flap lower portion 125e and second flap lower portion are engaged with the hinge 16 of the test switch blade 12, different portions along each of the first flap lower portion 125e and second flap lower portion may be pressed into engagement with the hinge 16 and allow the safety barrier 100 to roll downward. The downward push and roll allows the handle 14 to pass over the first flap 125 and the second flap 130 into a position to push the first flap 125 and the second flap 130 away from each other and allow the test switch blade to pass through the first flap 125 and the second flap 130 to actuate the test switch blade 12 into the closed position. Additionally, during the downward push and roll, the slanted portion 125d of first flap third portion 125c and the slanted portion of second flap third portion 130c may be adapted to press against a current jack to brace the first flap third portion 125c and second flap third portion 130c to prevent over movement of safety barrier 100 during closing of the test switch blade 12. Further, during the downward push and roll, engagement of the first flap lower portion 125e and the second flap lower portion with the hinge 16 may also prevent over movement of safety barrier 100 caused by the downward push.

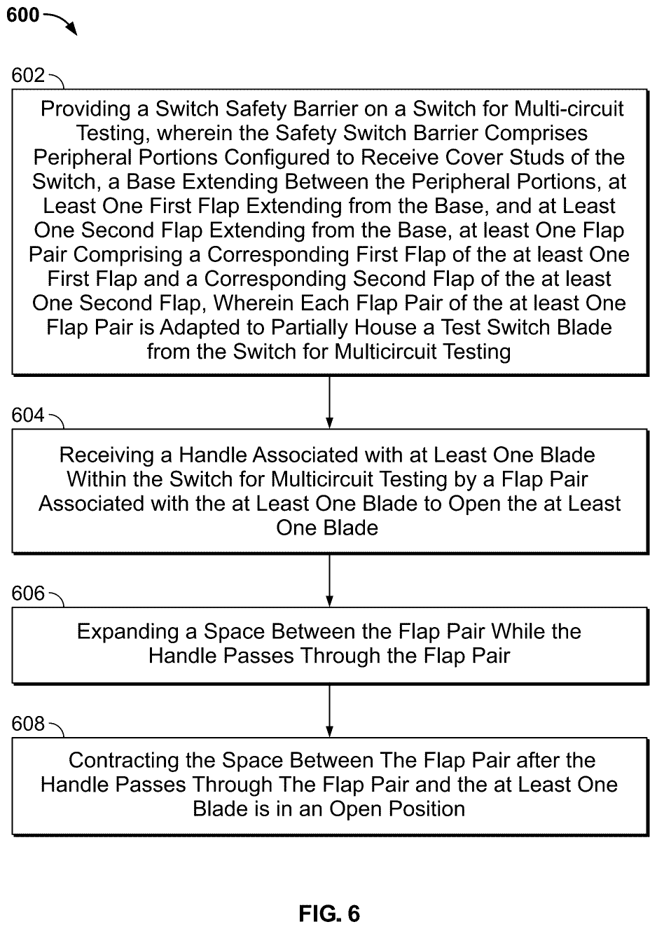

FIG. 6 is a flow chart outlining a method 600 for using the switch safety barrier 100.

In 602, the method 600 comprises providing a switch safety barrier 100 on a switch for multi-circuit testing 10. The safety switch barrier 100 comprises peripheral portions 110 configured to receive cover studs 13 of the switch 10 and a base 120 connecting the peripheral portions 110. The safety switch barrier 100 further comprises at least one first flap 125 extending from the base and at least one second flap 130 extending from the base 120, where each of the at least one second flap 130 is paired with one first flap 125 of the at least one first flap to form at least one flap pair 124.

In 604, the method 600 comprises receiving a handle 14 associated with at least one test switch blade 12 within the switch 10 for multi-circuit testing by a flap pair 124 of the at least one flap pair associated with the at least one test switch blade 12 to open the at least one test switch blade 12.

In 606, the method 600 comprises expanding a space between the flap pair 124 while the handle 14 passes through the flap pair 124.

In 608, the method 600 comprises contracting the space between the flap pair 124 after the handle 14 passes through the flap pair 124 and the at least one test switch blade 12 is in an open position.

Additionally, in an embodiment, method 600 may comprise blocking a test probe from insertion into the switch safety barrier using at least one blocking rib 160. Each of the at least one blocking rib 160 may extend from the base 120 between a first flap pair of the at least one flap pair 124 and a second flap pair of the at least one flap pair 124.

Further, in an embodiment, method 600 may comprise defining a clip receiving channel 150 by an exterior of each of the at least one flap pair. Additionally, method 600 may comprise preventing passing of the handle through the flap pair by a clip coupled to the flap pair using the clip receiving channel 150.

In an embodiment, method 600 may comprise defining a test probe receiving channel 140 by an interior of each of the at least one flap pair. Additionally, method 600 may comprise receiving a test probe in at least one of the test probe receiving channel 140.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary” or “example” embodiment are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences from the literal language of the claims.

We claim:

1. A safety barrier for a switch for multi-circuit testing comprising:
a base;
at least one first flap extending from the base;
at least one second flap extending from the base; and
at least one flap pair comprising a corresponding first flap of the at least one first flap and a corresponding second flap of the at least one second flap,
wherein each flap pair of the at least one flap pair is adapted to partially house a test switch blade from the switch for multi-circuit testing.

2. The switch safety barrier of claim 1, wherein each first flap comprises:
a first flap first portion extending from the base, wherein the first flap portion is concave relative to the corresponding second flap;
a first flap third portion, wherein the first flap third portion is convex relative to the corresponding second flap; and
a first flap second portion connecting the first flap first portion and first flap third portion.

3. The switch safety barrier of claim 2, wherein each first flap further comprises a first flap lower portion, wherein the first flap lower portion is adapted to engage a hinge of the test switch blade during closing of a test switch blade.

4. The switch safety barrier of claim 2, wherein each second flap comprises:
a second flap first portion extending from the base, wherein the first flap portion is concave relative to the corresponding second flap;
a second flap third portion, wherein the second flap third portion is convex relative to the first flap third portion; and
a second flap second portion connecting the second flap first portion and second flap third portion,
wherein the second flap second portion is substantially parallel to the first flap second portion,
wherein the second flap third portion and the first flap third portion define a widened opening.

5. The switch safety barrier of claim 3, further comprising a test probe guiding channel defined by an interior of the first flap first portion and an interior of the second flap first portion.

6. The switch safety barrier of claim 3, further comprising a clip receiving channel defined by an exterior of the first flap second portion and an exterior of the second flap second portion.

7. The switch safety barrier of claim 1, further comprising at least one blocking rib extending from the base between a first flap pair of the at least one flap pair and a second flap pair of the at least one flap pair.

8. A switch for multi-circuit testing comprising:
a switch body comprising at least one test switch blade;
cover studs extending from the switch body; and
a safety barrier coupled to the switch body, the safety barrier comprising:
peripheral portions configured to receive to the cover studs;
a base connecting the peripheral portions;
at least one first flap extending from the base;
at least one second flap extending from the base; and
at least one flap pair comprising a corresponding first flap of the at least one first flap and a corresponding second flap of the at least one second flap,
wherein each flap pair of the at least one flap pair is adapted to partially house one test switch blade from the at least one test switch blade.

9. The switch for multi-circuit testing of claim 8, wherein each first flap comprises:
a first flap first portion extending from the base, wherein the first flap portion is concave relative to the corresponding second flap;
a first flap third portion, wherein the first flap third portion is convex relative to the corresponding second flap; and
a first flap second portion connecting the first flap first portion and first flap third portion.

10. The switch for multi-circuit testing of claim 9, wherein each first flap further comprises a first flap lower portion, wherein the first flap lower portion is adapted to engage a hinge of the test switch blade during closing of a test switch blade.

11. The switch for multi-circuit testing of claim 9, wherein each second flap comprises:
a second flap first portion extending from the base, wherein the first flap portion is concave relative to the corresponding second flap;
a second flap third portion, wherein the second flap third portion is convex relative to the first flap third portion; and
a second flap second portion connecting the second flap first portion and second flap third portion,
wherein the second flap second portion is substantially parallel to the first flap second portion,
wherein the second flap third portion and the first flap third portion define a widened opening.

12. The switch for multi-circuit testing of claim 10, further comprising a test probe guiding channel defined by an interior of the first flap first portion and an interior of the second flap first portion.

13. The switch for multi-circuit testing of claim 10, further comprising a clip receiving channel defined by an exterior of the first flap second portion and an exterior of the second flap second portion.

14. The switch for multi-circuit testing of claim 8, further comprising at least one blocking rib extending from the base between a first flap pair of the at least one flap pair and a second flap pair of the at least one flap pair.

15. A method of using a switch safety barrier, comprising:
providing a switch safety barrier on a switch for multi-circuit testing, wherein the safety switch barrier comprises peripheral portions configured to receive cover studs of the switch, a base connecting the peripheral portions, at least one first flap extending from the base, at least one second flap extending from the base, and at least one flap pair comprising a corresponding first flap of the at least one first flap and a corresponding second flap of the at least one second flap, wherein each flap pair of the at least one flap pair is adapted to partially house a test switch blade from the switch for multi-circuit testing;
receiving a handle associated with at least one test switch blade within the switch for multi-circuit testing by a flap pair associated with the at least one test switch blade to open the at least one test switch blade;
expanding a space between the flap pair while the handle passes through the flap pair; and
contracting the space between the flap pair after the handle passes through the flap pair and the at least one test switch blade is in an open position.

16. The method of claim 15, further comprising blocking a test probe from insertion into the switch safety barrier using blocking ribs at least one blocking rib extending from the base between a first flap pair of the at least one flap pair and a second flap pair of the at least one flap pair.

17. The method of claim 15, further comprising defining a clip receiving channel by an exterior of each of the at least one flap pair.

18. The method of claim 17, further comprising preventing passing of the handle through the flap pair by a clip coupled to the flap pair using the clip receiving handle.

19. The method of claim 15, further comprising defining a test probe receiving channel by an interior of each of the at least one flap pair.

20. The method of claim 19, further comprising receiving a test probe in at least one of one test probe receiving channel defined by the at least one flap pair.
